(19) United States
(12) Patent Application Publication
(10) Pub. No.: US 2009/0021399 A1
(43) Pub. Date: Jan. 22, 2009

(54) Increasing the Number of Keys Supported by a Keyboard Controller

(75) Inventors: Yuval Itkin, Zoran (IL); Ariel Goldfarb, Tel-Mond (IL)

Correspondence Address: WOLFF LAW OFFICE, PLLC, P.O. BOX 9855, CHAPEL HILL, NC, 27515-9855, US

(73) Assignee: DSP Group Limited

(21) Appl. No.: 11/778,640

(22) Filed: Jul. 16, 2007

(51) Int. Cl. H03K 17/94

(52) U.S. Cl. 341/22

(57) ABSTRACT

An enhanced keyboard for controlling a device, including: a keypad with a plurality of depressible keys; a controller with a pre-designed integer number of output lines (J) and a pre-designed integer number of input lines (K); a printed circuit with switch mechanisms that are adapted to enable an electronic signal to pass from a specific output line of the controller to a specific input line of the controller responsive to depressing a specific key of the keypad; and one or more additional switch mechanisms that are adapted to enable an electronic signal to pass from a specific output line of the controller to at least two specific input lines of the controller responsive to depressing a specific key of the keypad.

### FIELD OF THE INVENTION

The present invention relates generally to the design of keyboards for electronic devices and specifically to increasing the number of keys supported by the keyboard controller.

### BACKGROUND OF THE INVENTION

Many devices use keyboards for the functionality of the device, for example a computer, a mobile telephone a calculator, a PDA and other devices. Generally, the keyboard is controlled by a controller with a limited number of output lines and a limited number of input lines. In a typical keyboard the output lines and the input lines of the controller are positioned perpendicular to each other forming a matrix of intersections. Each intersection accommodates a single key from the keyboard. The controller scans the keyboard to identify pressed keys by alternately sending a signal on each output line. When a key is pressed it shorts between the output line and the input line at the intersection beneath it, so that the signal sent by the controller on the output line is accepted by the controller on one of the input lines. The controller can determine, which key has been pressed since it knows, which output line was provided a signal at the moment a signal was identified on an input line, and the controller knows which input line received the signal.

Typically the controller scans all output lines and all input lines at a rate, which is sufficiently greater than the rate that a person would type, for example 100-1000 times a second, so that all key presses by the person will be detected. The controller is programmed to determine the identity of the keys pressed and optionally, the duration during, which the key was pressed. The electronic device can then take actions responsive to this information.

A controller with more output lines and/or more input lines can support more keys, for example a controller with 5 output lines and 4 input lines forms a 5×4 matrix and can support 20 keys, whereas a controller with 5 output lines and 5 input lines can support 25 keys.

Generally the controller is provided as a microchip. The manufacturing cost of the controller generally increases with the increase in the number of input/output lines, due to various factors such as chip size, transistor density and packaging. The difference is especially important in the manufacture of small devices, for example a watch calculator or mobile telephone. Generally if a smaller controller can be used to support the desired number of keys this would be beneficial since it would reduce requirements regarding the size of the controller and manufacturing cost. Likewise if the same controller could be used to support more keys, the cost of adding more keys would be reduced, for example to support a keyboard on a mobile telephone with keys for the entire alphabet using the same keyboard controller as used to support only the numbers and functions provided in older models.

### SUMMARY OF THE INVENTION

An aspect of an embodiment of the invention, relates to a method of increasing the number of keys supported by a key controller by designing the matrix of keys to provide one key for each intersection between an input line and an output line, and provide an additional key on the input line between each pair of intersections. In an exemplary embodiment of the invention, each intersection key is identified to the controller by shorting between an input line and an output line, each additional key is identified by shorting between an output line and two input lines, for example from both sides of the additional key. In some embodiments of the invention, more than one additional key is provided between each pair of intersections, for example 2 or 3 keys. Optionally, each additional key is identified by shorting an additional input line, for example a second additional key shorts three input lines and a third additional key shorts four input lines. In an exemplary embodiment of the invention, a multilayer substrate is used to enable connecting additional keys between each intersection.

There is thus provided according to an exemplary embodiment of the invention, an enhanced keyboard for controlling a device, comprising:

a keypad with a plurality of depressible keys;

a controller with a pre-designed integer number of output lines (J) and a pre-designed integer number of input lines (K);

a printed circuit with switch mechanisms that are adapted to enable an electronic signal to pass from a specific output line of the controller to a specific input line of the controller responsive to depressing a specific key of the keypad; and

one or more additional switch mechanisms that are adapted to enable an electronic signal to pass from a specific output line of the controller to at least two specific input lines of the controller responsive to depressing a specific key of the keypad.

Optionally, the additional switch mechanisms pass an electronic signal to exactly two input lines. Alternatively, some of the additional switch mechanisms pass an electronic signal to more than two input lines. In an exemplary embodiment of the invention, the printed circuit is single layered. Alternatively, the printed circuit is multilayered. In an exemplary embodiment of the invention, the output lines form columns on the printed circuit and the input lines form rows on the printed circuit and the switch mechanisms are positioned at the intersection points between the columns and the rows of the printed circuit to create a short between them when a key is depressed; and the additional switch mechanisms are positioned between the intersection points. Optionally, the enhanced keyboard supports more than K times J keys on the keypad with the controller. In an exemplary embodiment of the invention, the enhanced keyboard supports more than 2K-1 times J keys on the keypad with the controller. Optionally, some of the additional switch mechanisms are adapted to pass on a signal from a specific output line of the controller to two specific input lines of the controller and some of the additional switch mechanisms are adapted to pass on a signal from a specific output line of the controller to three specific input lines of the controller.

There is further provided according to an exemplary embodiment of the invention, a method of increasing the number of keys from the keypad of a keyboard supported by a keyboard controller with a pre-designed number of output lines (I) and a pre-designed number of input lines (K), including:

preparing a printed circuit with switch mechanisms to enable an electronic signal to pass from a specific output line of the controller to a specific input line of the controller responsive to depressing a specific key from the keypad; and

adding one or more additional switch mechanisms that enable an electronic signal to pass from a specific output line of the controller to at least two specific input lines of the controller responsive to the depression of a specific key of the keypad.

### BRIEF DESCRIPTION OF THE DRAWINGS

The present invention will be understood and better appreciated from the following detailed description taken in conjunction with the drawings. Identical structures, elements or parts, which appear in more than one figure, are generally labeled with the same or similar number in all the figures in which they appear, wherein:

FIG. 1A is a schematic illustration of a keyboard circuit, according to an exemplary embodiment of the invention;

FIG. 1B is a schematic illustration of the keypad of a keyboard for use with a keyboard circuit, according to an exemplary embodiment of the invention;

FIG. 2A is a schematic illustration of a first layer of a multilayer keyboard circuit, according to an exemplary embodiment of the invention; and

FIG. 2B is a schematic illustration of a second layer of a multilayer keyboard circuit, according to an exemplary embodiment of the invention.

### DETAILED DESCRIPTION

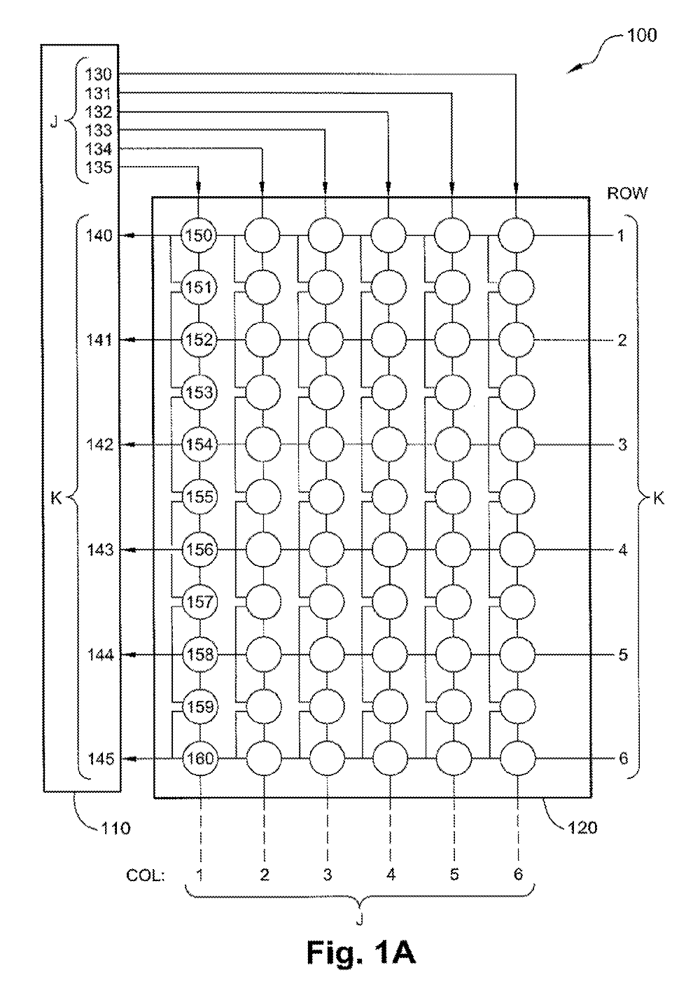

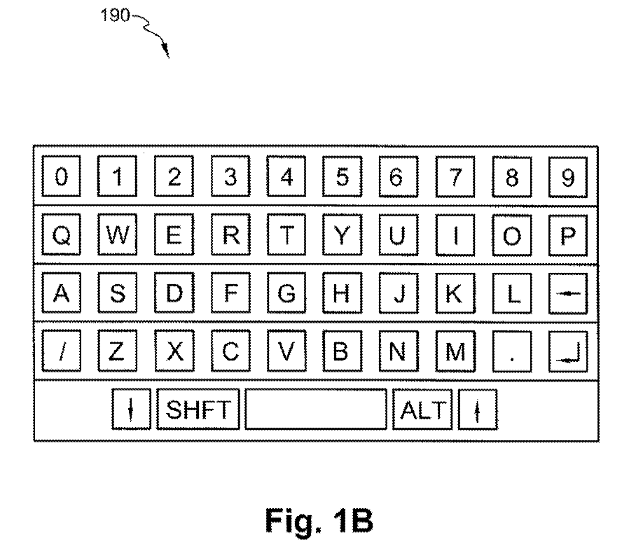

FIG. 1A is a schematic illustration of a keyboard circuit 100, according to an exemplary embodiment of the invention. In an exemplary embodiment of the invention, keyboard circuit 100 comprises a controller 110 (e.g. a microchip such as Intel 8048) with a plurality of output lines (130-135, J columns) and a plurality of input lines (140-145, K rows). Circuit 100 additionally comprises a substrate 120 on which electric lines are printed to form a matrix for placing keys and a switching mechanism to short between an input line and an output line when a key is pressed. In an exemplary embodiment of the invention, each intersection between output lines 130-135 and input lines 120-125 is adapted to accommodate a switch mechanism (e.g. 150, 152, 154, 156, 158 and 160) and keyboard keys. In an exemplary embodiment of the invention, controller 110 alternately provides a signal on each output line 130-135 of controller 110 at a rapid scanning rate (e.g. 100-1000 times a second). Optionally, when a key above a specific intersection is pressed the switch mechanism (e.g. 150) shorts between the output line and the input line that meet at the intersection on substrate 120. Controller 110 detects the signal on the input line and is then able to determine the row and column of the key that was pressed.

In an exemplary embodiment of the invention, an additional switch mechanism (e.g. 151, 153, 155, 157, and 159) is provided on each column formed by the output line (the J columns) between the intersection points of the column with the input lines (the K rows). The additional switch mechanism electrically shorts the output line with the input line of the two delimiting input lines when it is pressed. Thus when a key above an additional switch mechanism is pressed controller 110 receives a signal on two input lines and can determine the identity of the pressed key according to the column of the key and the two rows delimiting the key. Optionally, controller 110 is programmed to provide the appropriate key codes according to the above enhancement to the keyboard layout.

FIG. 1B is a schematic illustration of the keypad 190 of a keyboard for use with keyboard circuit 100, according to an exemplary embodiment of the invention. Keypad 190 is illustrated with 45 keys and would classically require a controller with at least 45 intersection points to support all the keys, for example with 7 output lines and 7 input lines, providing a total of 49 intersection points. In an exemplary embodiment of the invention, controller 110 with J output lines and K input lines can support J×(2K-1) keys in contrast to J×K keys in the classical use of controller 110. In the case illustrated in FIG. 1A with 6 output lines and 6 input lines, controller 110 is adapted to support 66 keys instead of 36. Thus according to the above description a 6×6 controller could be used instead of a 7×7 controller.

In an exemplary embodiment of the invention, by pressing simultaneously two keys from two adjacent rows (e.g. rows 1 and 2 of the K rows) controller 110 will determine that the additional key was pressed (e.g. the key supported by switch mechanism 151). This feature can be used to implement a cheaper keyboard that provides the additional key values without actually providing keys for these values. Optionally, the additional key values are marked in the intermediate area between the classical key positions (above the intersections) without actually providing keys for these values. When a user wants the additional values he/she presses the keys above and below the value marked in the intermediate area simultaneously. Thus the above method can be used to provide additional key values for a keyboard by reprogramming controller 110 without replacing the controller and without adding keys. Optionally, to enhance simplicity for the user, substrate 120 is prepared with the additional switch mechanisms (e.g. 151, 153, 155, 157, and 159) and the additional keys to activate the switch mechanisms.

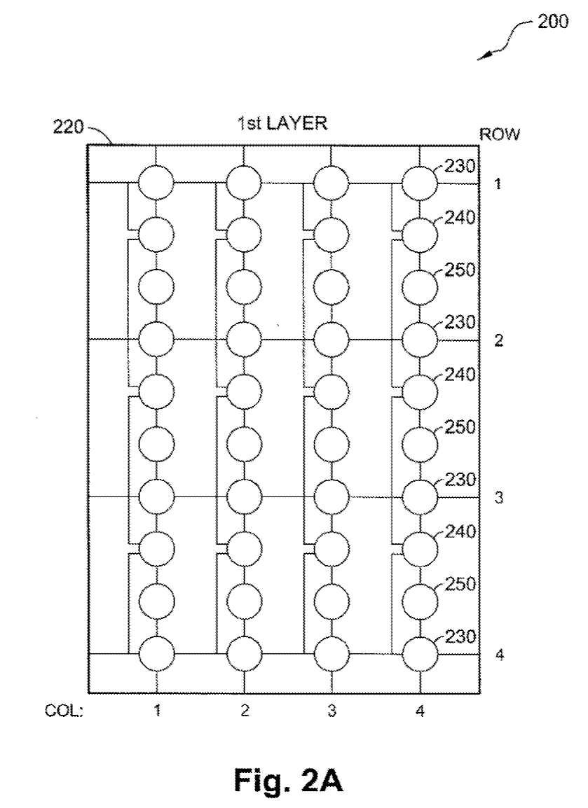

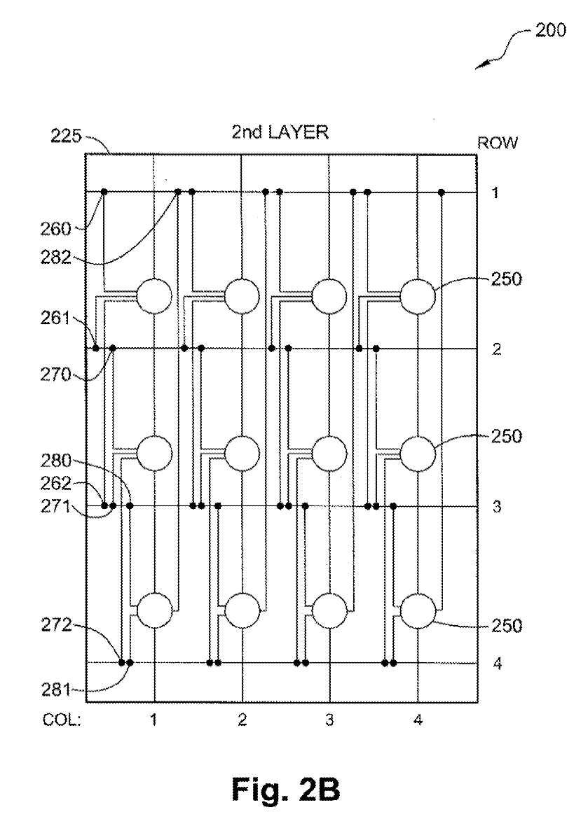

FIG. 2A is a schematic illustration of a first layer 220 of a multilayer keyboard circuit 200, according to an exemplary embodiment of the invention, and FIG. 2B is a schematic illustration of a second layer 225 of a multilayer keyboard circuit, according to an exemplary embodiment of the invention. In an exemplary embodiment of the invention, circuit 200 accommodates 4 output lines, 4 input lines. Optionally, 2 additional switch mechanisms (240, 250) are added between every two switch mechanisms 230, located at the intersection points. Optionally, substrate 120 includes first layer 220 to provide the classical printed circuit layout and support the first additional switch mechanism 240 as described above regarding FIG. 1. Additionally, substrate 120 includes second layer 225 for example printed on the bottom side of the substrate, or internal to the substrate to support adding a second switch mechanism between every two intersection points on each column. In some embodiments of the invention, the position of the additional switch mechanisms and/or the supported keys may vary, causing the printed circuit to require additional layers and/or to be more complex or less complex.

In an exemplary embodiment of the invention, when pressing a key supported by a second additional switch mechanism 250, switch mechanism 250 provides the signal from the output line (e.g. 130-135) to 3 input lines (e.g. 140-145). Optionally, controller 110 is programmed to recognize that when a signal is transmitted on one output line (e.g. 130-135) and is detected on 3 input lines (e.g. 140-145) it determines the identity of the second switch mechanism 250 that was shorted. As shown in FIG. 2 for the second layer if second switch mechanism 250 between rows 1 and 2 is shorted, the signal is provided to points 260, 261 and 262 (rows 1,2,and 3), between rows 2 and 3 points 270, 271, and 272 (rows 2,3,and 4) are shorted, and between rows 3 and 4 points 280, 281 and 282 (rows 3, 4, and 1) are shorted.

In an exemplary embodiment of the invention, by using two additional switch mechanisms between each intersection point, a controller with J output lines and K input lines can support J×(3K-2) keys in contrast to J×K keys in the classical use of controller 110. In the case illustrated in FIG. 2 with 4 output lines and 4 input lines, controller 110 is adapted to support 40 keys instead of 16.

In some embodiments of the invention, controller 110 is adapted to support even more keys by adding more switch mechanisms between each pair of intersection points. Optionally, substrate 120 is provided with more printed circuit traces to accommodate the additional switch mechanisms.

In some embodiments of the invention, the geometry of the substrate may vary, for example by being designed in any shape with the keys arranged in any order, and not necessarily rectangular with a rectangular matrix as described above. Additionally, in some embodiments of the invention, only some of the possible additional keys are actually added, depending on the actual number of keys required for the electronic device

It should be appreciated that the above described methods and apparatus may be varied in many ways, including omitting or adding steps, changing the order of steps and the type of devices used. It should be appreciated that different features may be combined in different ways. In particular, not all the features shown above in a particular embodiment are necessary in every embodiment of the invention. Further combinations of the above features are also considered to be within the scope of some embodiments of the invention.

It will be appreciated by persons skilled in the art that the present invention is not limited to what has been particularly shown and described hereinabove. Rather the scope of the present invention is defined only by the claims, which follow.

1. An enhanced keyboard for controlling a device, comprising:
a keypad with a plurality of depressible keys;
a controller with a pre-designed integer number of output lines (J) and a pre-designed integer number of input lines (K);
a printed circuit with switch mechanisms that are adapted to enable an electronic signal to pass from a specific output line of the controller to a specific input line of the controller responsive to depressing a specific key of the keypad; and
one or more additional switch mechanisms that are adapted to enable an electronic signal to pass from a specific output line of the controller to at least two specific input lines of the controller responsive to depressing a specific key of the keypad.

2. An enhanced keyboard according to claim 1, wherein said additional switch mechanisms pass an electronic signal to exactly two input lines.

3. An enhanced keyboard according to claim 1, wherein some of said additional switch mechanisms pass an electronic signal to more than two input lines.

4. An enhanced keyboard according to claim 1, wherein said printed circuit is single layered.

5. An enhanced keyboard according to claim 1, wherein said printed circuit is multilayered.

6. An enhanced keyboard according to claim 1, wherein said output lines form columns on said printed circuit and said input lines form rows on said printed circuit and said switch mechanisms are positioned at the intersection points between the columns and the rows of said printed circuit to create a short between them when a key is depressed; and said additional switch mechanisms are positioned between the intersection points.

7. An enhanced keyboard according to claim 1, wherein said enhanced keyboard supports more than K times J keys on said keypad with said controller.

8. An enhanced keyboard according to claim 1, wherein said enhanced keyboard supports more than 2K-1 times J keys on said keypad with said controller.

9. An enhanced keyboard according to claim 1, wherein some of said additional switch mechanisms are adapted to pass on a signal from a specific output line of the controller to two specific input lines of the controller and some of said additional switch mechanisms are adapted to pass on a signal from a specific output line of the controller to three specific input lines of the controller.

10. A method of increasing the number of keys from the keypad of a keyboard supported by a keyboard controller with a pre-designed number of output lines (J) and a pre-designed number of input lines (K), comprising:
preparing a printed circuit with switch mechanisms to enable an electronic signal to pass from a specific output line of the controller to a specific input line of the controller responsive to depressing a specific key from the keypad; and
adding one or more additional switch mechanisms that enable an electronic signal to pass from a specific output line of the controller to at least two specific input lines of the controller responsive to the depression of a specific key of the keypad.
